(19) United States
(12) Patent Application Publication
(10) Pub. No.: US 2019/0099855 A1
(43) Pub. Date: Apr. 4, 2019

(54) POLISHING APPARATUS

(71) Applicant: DISCO CORPORATION, Tokyo (JP)

(72) Inventors: Norihisa ARIFUKU, Tokyo (JP); Makoto SARUMIDA, Tokyo (JP)

(21) Appl. No.: 16/145,386

(22) Filed: Sep. 28, 2018

(30) Foreign Application Priority Data
Oct. 2, 2017 (JP) 2017-192600

(51) Int. Cl. B24B 37/10; B24B 37/22; H01L 21/306

(52) U.S. Cl. CPC B24B 37/107; H01L 21/30625; B24B 37/22

(57) ABSTRACT

A polishing pad of a polishing apparatus contains abrasive grains, and is formed with a plurality of grooves in an adhesion surface to be adhered to a support base. The polishing pad has a plurality of communication holes penetrating to a flat polishing surface, and a polishing liquid is distributed into the plurality of grooves and is supplied to the polishing surface through the plurality of communication holes.

### BACKGROUND OF THE INVENTION

### Field of the Invention

The present invention relates to a polishing apparatus for polishing a wafer.

### Description of the Related Art

In the semiconductor device manufacturing step, a semiconductor wafer formed with a plurality of devices is divided along streets, to form semiconductor devices. For realizing reductions in size and weight of semiconductor devices, the back surface of the semiconductor wafer is ground before dividing the semiconductor wafer. When the semiconductor wafer is thus ground, a grinding strain layer composed of microcracks which is approximately 1 μm in thickness is formed on the back surface of the semiconductor wafer. When the thickness of the semiconductor wafer is reduced to or below 100 μm, the grinding strain layer reduces the die strength of the semiconductor devices.

In order to solve such a problem, after the semiconductor wafer is ground to a predetermined thickness, the back surface of the semiconductor wafer is subjected to polishing, wet etching, dry etching or the like, to remove the grinding strain layer formed on the back surface of the semiconductor wafer, thereby preventing the die strength of the semiconductor devices from being lowered.

On the other hand, in a semiconductor wafer formed with a plurality of devices having a memory function such as dynamic random access memories (DRAMs) or flash memories, removal of the grinding strain layer reduces the memory function. It is considered that when the grinding strain layer on the back surface of the semiconductor wafer is removed, the gettering effect is lost, and metallic ions of copper or the like contained in the inside of the semiconductor wafer are floated to the front surface side where the devices are formed, resulting in generation of a current leak.

In order to solve such a problem, a polishing pad has been proposed for forming a gettering layer composed of microcracks which is 0.2 μm or less in thickness on the back surface of the semiconductor wafer (see, for example, Japanese Patent Laid-open No. 2015-46550). The polishing pad of Japanese Patent Laid-open No. 2015-46550 is configured by impregnating a non-woven fabric with a mixture prepared by mixing solid-phase reaction particulates (abrasive grains for polishing) for inducing a solid-phase reaction with silicon and gettering layer forming particulates (abrasive grains for gettering) higher in Mohs hardness than silicon into a liquid binding material.

After a semiconductor wafer is ground to a predetermined thickness, the back surface of the semiconductor wafer is polished by this polishing pad while supplying an alkaline solution. This permits the solid-phase reaction particulates in the polishing pad to function (act), whereby the grinding strain layer formed by grindstone and left on the back surface of the semiconductor wafer is removed. Thereafter, the back surface of the semiconductor wafer is polished by this polishing pad while supplying pure water. This permits the gettering layer forming particulates to function, whereby slight flaws are formed on the back surface of the semiconductor wafer, and a gettering layer is thereby formed. The gettering layer restrains the die strength of the semiconductor devices from being lowered, and, semiconductor devices with a gettering effect are manufactured.

### SUMMARY OF THE INVENTION

Here, a polishing pad is generally formed with a plurality of grooves in its polishing surface for polishing a semiconductor wafer. At the time of polishing the semiconductor wafer, an alkaline solution and pure water supplied to the polishing pad is distributed to the whole area of the polishing surface through the plurality of grooves. In this state, the polishing pad in rotation is put into rotating contact with the semiconductor wafer, whereby the semiconductor wafer is polished. However, angular parts between groove side surfaces and the polishing surface collide on an outer peripheral edge of the semiconductor wafer repeatedly, whereby a load is exerted on the outer peripheral edge, and, in the case of a thin semiconductor wafer, edge chipping may be generated.

Accordingly, it is an object of the present invention to provide a polishing apparatus capable of favorably polishing a wafer through distributing a polishing liquid throughout a polishing pad and preventing edge chipping even in the case of a thin wafer.

In accordance with an aspect of the present invention, there is provided a polishing apparatus polishing a wafer, including: a chuck table that holds the wafer on an upper face thereof; and a polishing unit that polishes the wafer held by the chuck table. The polishing unit includes a rotary spindle, a mounter fixed to a tip of the rotary spindle, and a polishing tool detachably mounted to the mounter. The polishing tool includes a circular annular support base communicating with a polishing liquid supply unit and provided in its center with a supply hole through which to pass a polishing liquid, and a polishing pad adhered to a support surface of the support base. The polishing pad contains abrasive grains, and is formed with a plurality of grooves in an adhesion surface to be adhered to the support surface. The polishing pad has a plurality of communication holes penetrating from the adhesion surface to a flat polishing surface which is a surface opposite to the adhesion surface, and the polishing liquid supplied from the supply hole is distributed into the plurality of grooves and is supplied to the polishing surface through the plurality of communication holes.

In accordance with another aspect of the present invention, there is provided a polishing apparatus polishing a wafer, including: a chuck table that holds the wafer on an upper face thereof; and a polishing unit that polishes the wafer held by the chuck table. The polishing unit includes a rotary spindle, a mounter fixed to a tip of the rotary spindle, and a polishing tool detachably mounted to the mounter. The polishing tool includes a circular annular support base communicating with a polishing liquid supply unit and provided in its center with a supply hole through which to pass a polishing liquid, and a polishing pad adhered to a support surface of the support base. The polishing pad is formed by putting solid-phase reaction particulates inducing a solid-phase reaction with silicon into a liquid binding material, impregnating a non-woven fabric with the resulting material and drying the impregnated non-woven fabric, and is formed with a plurality of grooves in an adhesion surface to be adhered to the support surface. The non-woven fabric has a plurality of communication holes penetrating from the adhesion surface to a flat polishing surface which is a surface opposite to the adhesion surface, and the polishing liquid supplied from the supply hole is distributed into the plurality of grooves and is supplied to the polishing surface through the plurality of communication holes.

According to these configurations, in the polishing pad, the adhesion surface to be adhered to the support surface of the support base is formed with the plurality of grooves, whereas the polishing surface is not formed with grooves, and, therefore, the wafer can be polished by the flat polishing surface. Since there is no possibility that angular parts between groove side surfaces and the polishing surface might collide on the wafer, the wafer can be polished with the abrasive grains while preventing generation of chipping at an outer peripheral edge of the wafer. In addition, the polishing liquid supplied through the supply hole in the support base is distributed into the plurality of grooves formed in the adhesion surface of the polishing pad, and is further supplied from the grooves to the polishing surface through the communication holes. As a result of these, the wafer can be favorably polished through distributing the polishing liquid throughout the polishing pad and while preventing the generation of edge chipping even in the case of a thin wafer.

According to the present invention, a wafer can be favorably polished through distributing a polishing liquid throughout a polishing pad and while preventing the generation of edge chipping even in the case of a thin wafer.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view of a polishing apparatus according to the present embodiment;

FIG. 2 is an illustration of polishing by a polishing pad formed with grooves in a polishing surface;

FIGS. 3A and 3B are illustrations of a polishing tool having the polishing pad according to the present embodiment;

FIGS. 4A and 4B are figures for explaining the flow of a polishing liquid according to the present embodiment;

FIG. 5 is a figure depicting a strain layer removing step according to the present embodiment; and

FIGS. 6A and 6B are figures depicting a gettering layer forming step according to the present embodiment.

### DETAILED DESCRIPTION OF THE PREFERRED EMBODIMENT

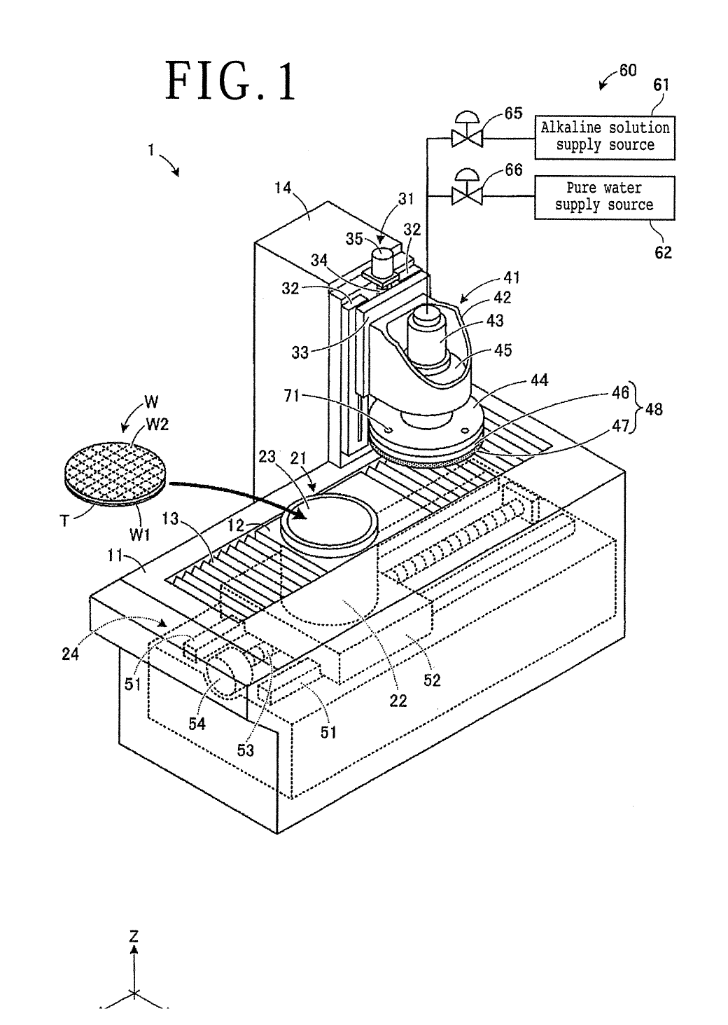

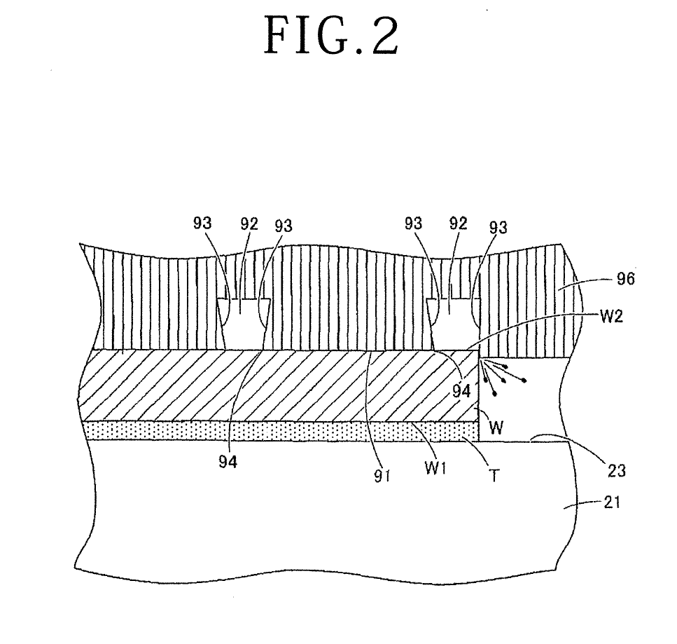

A polishing apparatus will be described below, referring to the attached drawings. FIG. 1 is a perspective view of a polishing apparatus according to the present embodiment. FIG. 2 is an illustration of polishing by a polishing pad formed with grooves in a polishing surface. Note that the polishing apparatus according to the present embodiment is not limited to the one as depicted in FIG. 1, and may be mounted in a full automatic type processing apparatus by which a series of processings such as grinding, polishing and cleaning are performed fully automatically.

As illustrated in FIG. 1, the polishing apparatus 1 is configured to polish a wafer W by chemical mechanical polishing (CMP) by use of a polishing pad 47 which will be described later. The wafer W is a silicon wafer, in which a plurality of streets are formed in a grid pattern on a front surface W1, and devices (not depicted) such as integrated circuits (ICs) and large-scale integrations (LSIs) are formed in regions partitioned by the streets. In grinding a back surface W2 of the wafer W to thin the wafer W to a predetermined thickness (for example, 100 μm), a protective tape T as a protective member is adhered to the front surface W1 of the wafer W, for protecting the devices formed on the front surface W1 of the wafer W. The wafer W is held by a chuck table 21, which will be described later, with the back surface W2 as a work surface on the upper side.

An upper face of a base 11 of the polishing apparatus 1 is formed with a rectangular opening extending in a Y-axis direction, and the opening is covered with a table cover 12 movable together with the chuck table 21 and a bellows-like waterproof cover 13. Under the waterproof cover 13, there are provided moving means 24 moving the chuck table 21 in the Y-axis direction, and rotating means 22 continuously rotating the chuck table 21. At an upper face of the chuck table 21, a holding surface 23 for holding the wafer W through the protective tape T is formed from a porous material. The holding surface 23 is connected to a suction source (not depicted) through a passage inside the chuck table 21.

The moving means 24 includes a pair of guide rails 51 disposed in the base 11 in parallel to the Y-axis direction, and a motor-driven Y-axis table 52 disposed slidably on the pair of guide rails 51. A nut section (not depicted) is formed on a rear face side of the Y-axis table 52, and a ball screw 53 is in screw engagement with the nut section. With a driving motor 54 connected to one end portion of the ball screw 53 being driven to rotate, the chuck table 21 is moved in the Y-axis direction along the pair of guide rails 51. The rotating means 22 is provided on the Y-axis table 52, and supports the chuck table 21 rotatably around a Z-axis.

A column 14 is disposed on the base 11, and the column 14 is provided with processing feeding means 31 processing feeding of a polishing unit (polishing means) 41 in the Z-axis direction. The processing feeding means 31 includes a pair of guide rails 32 disposed on the column 14 in parallel to the Z-axis direction, and a motor-driven Z-axis table 33 disposed slidably on the pair of guide rails 32. A nut section (not depicted) is formed on a rear face side of the Z-axis table 33, and a ball screw 34 is in screw engagement with the nut section. With the ball screw 34 rotationally driven by a driving motor 35 connected to one end portion of the ball screw 34, the polishing unit 41 is put into processing feeding along the guide rails 32.

The polishing unit 41 is mounted to a front face of the Z-axis table 33 through a housing 42, and is provided with a polishing tool 48 at a lower portion of a rotary spindle 43. The rotary spindle 43 is provided with a flange 45, and the polishing unit 41 is supported on the housing 42 through the flange 45. A mounter 44 is mounted to a lower portion of the rotary spindle 43, and the polishing tool 48 including a support base 46 and a polishing pad 47 is mounted to the mounter 44. A polishing liquid supply unit (polishing liquid supplying means) 60 for supplying a polishing liquid to the polishing pad 47 is connected to the polishing unit 41. When a valve 65 is opened, an alkaline solution is supplied to the polishing unit 41, and when a valve 66 is opened, pure water is supplied to the polishing unit 41. The polishing liquid includes the pure water, as well as the alkaline solution or the like.

The polishing apparatus 1 is provided with a control section (not depicted) for integrated control of components of the polishing apparatus 1. The control section controls the valves 65 and 66. The control section includes a processor for performing various processes, a memory and the like. The memory includes one or a plurality of storage media such as read only memory (ROM) and random access memory (RAM). In the polishing apparatus 1 configured in this way, while being rotated around the Z-axis, the polishing pad 47 is brought closer to the wafer W held by the chuck table 21. Then, the polishing pad 47 makes rotating contact with the back surface W2 of the wafer W, whereby the wafer W is polished.

Here, as depicted in FIG. 2, as a polishing pad 96, there has been known one provided in its polishing surface 91 with grooves 92 for assisting supply of a polishing liquid, and, with the polishing liquid distributed to the whole area of the polishing surface 91 through the grooves 92, the wafer W is polished in a favorable manner. However, as illustrated in FIG. 2, the groove 92 in the polishing pad 96 has an angular part 94 between a groove side surface 93 and the polishing surface 91, and when the angular parts 94 of the polishing pad 96 repeatedly collide against an outer peripheral edge of the wafer W at the time of polishing, a load is exerted on the outer peripheral edge, and the outer peripheral edge may be chipped where the wafer W is thin. In view of this, in the present embodiment, the polishing pad is formed with grooves on the side of an adhesion surface to be adhered to the support base, whereby the polishing surface is formed to be flat, and chipping of the outer peripheral edge of the wafer W by the angular parts 94 of the grooves 92 is prevented from occurring.

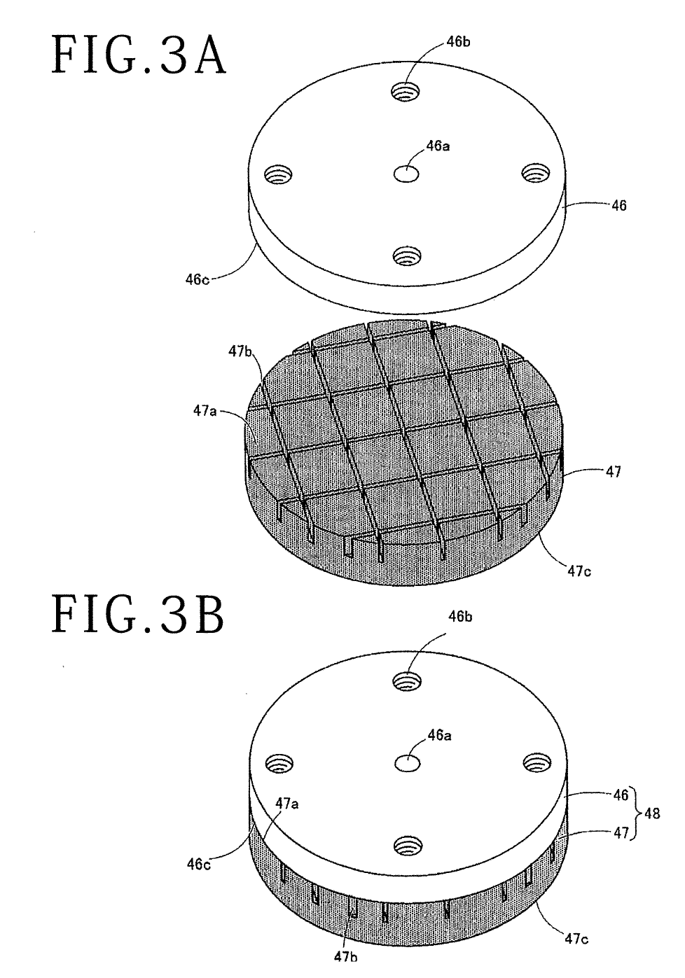

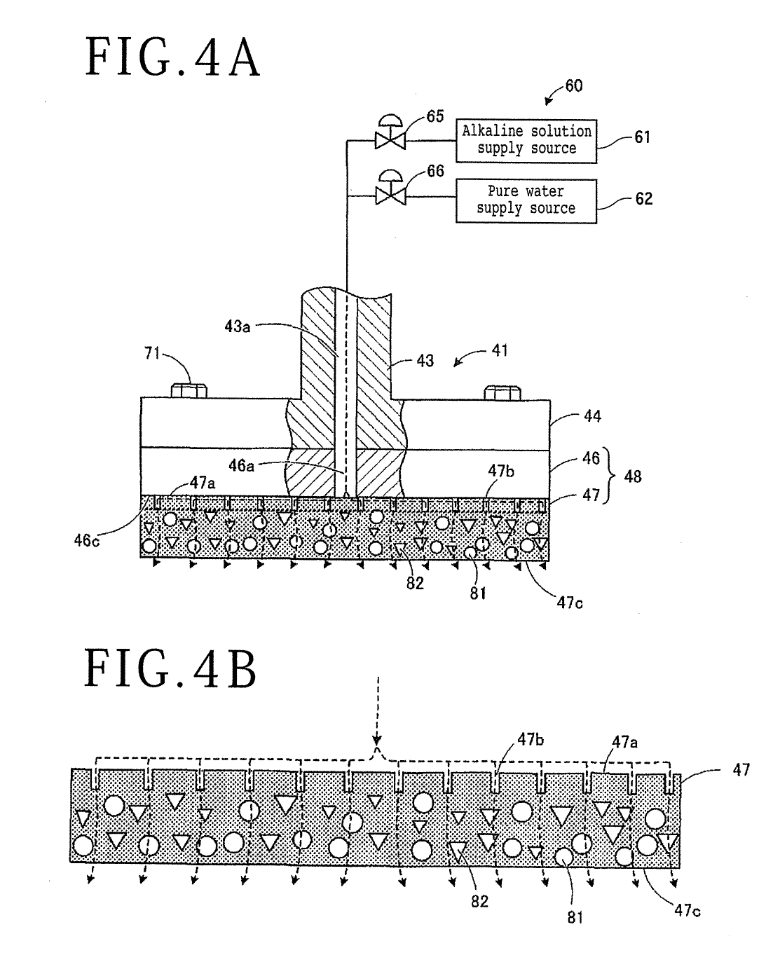

Referring to FIGS. 3A and 3B, the configuration of the polishing pad 47 will be described in detail below. FIGS. 3A and 3B are illustrations of the polishing tool having the polishing pad according to the present embodiment. FIG. 3A is a figure depicting a state before the polishing pad is adhered to the support base. FIG. 3B is a perspective view of the polishing tool. FIGS. 4A and 4B are figures for explaining the flow of the polishing liquid according to the present embodiment. FIG. 4A is a figure for explaining the flow of the polishing liquid in the polishing unit. FIG. 4B is a figure for explaining the flow of the polishing liquid in the polishing pad.

As depicted in FIG. 3A, the polishing tool 48 (see FIG. 3B) has a configuration in which the polishing pad 47 is adhered to the support base 46 having a circular annular shape. The support base 46 is formed from an aluminum alloy or the like, and is provided in its central portion with a supply hole 46a through which to pass the polishing liquid. In addition, the support base 46 is formed with female screw holes 46b at intervals along the circumferential direction thereof. A lower face of the support base 46 forms a support surface 46c for the polishing pad 47, and the polishing pad 47 is adhered to the support surface 46c.

The polishing pad 47 is formed in a circular disk shape. An upper face of the polishing pad 47 is an adhesion surface 47a to be adhered to the support surface 46c of the support base 46, and the adhesion surface 47a is formed with a plurality of intersecting grooves 47b serving as passages for the polishing liquid. The passages for the polishing liquid of the grooves 47b are formed to be larger than communication holes (communication pores) which will be described later. This ensures that the polishing liquid supplied to the polishing pad 47 is distributed into the grooves 47b with preference over the communication holes. In other words, the polishing liquid spreads in radial directions of the polishing pad 47 along the grooves 47b in the adhesion surface 47a, before passing through the communication holes to reach the polishing surface 47c. The polishing liquid is distributed in the radial directions of the polishing pad 47 by the grooves 47b and thereafter the polishing liquid is supplied from the grooves 47b to the polishing surface 47c through the communication holes, and, therefore, the polishing liquid can be distributed throughout the polishing pad 47. The depth and width of the grooves 47b are not particularly limited, and can be modified according to processing conditions, provided that the passages of the grooves 47b are larger than the communication holes. In the case where the polishing liquid is high in viscosity and can not easily flow through the grooves 47b, the grooves 47b are enlarged in depth or enlarged in width, whereby the polishing liquid is permitted to easily flow through the grooves 47b. In addition, a lower face of the polishing pad 47 is the polishing surface 47c for polishing the wafer W, and is formed to be flat. The polishing pad 47 is formed, for example, to be 450 mm in diameter and 10 mm in thickness. As depicted in FIG. 3B, the adhesion surface 47a of the polishing pad 47 is adhered to the support surface 46c of the support base 46 by a double-sided adhesive tape, whereby the polishing tool 48 is configured.

The polishing pad 47 is formed, for example, by putting solid-phase reaction particulates 81 for inducing a solid-phase reaction with silicon into a liquid binding material as abrasive grains, impregnating a non-woven fabric with the resulting material and drying the impregnated non-woven fabric (see FIGS. 4A and 4B). As the abrasive grains, gettering layer forming particulates 82 higher in Mohs hardness than silicon may be contained in the polishing pad 47.

As the solid-phase reaction particulates 81, there may be used particulates of SiO₂, CeO₂, ZrO₂ and the like, and the particle diameter of the solid-phase reaction particulates 81 is preferably not less than 2 μm, for example. The gettering layer forming particulates 82 preferably have a Mohs hardness of not less than 9. As the gettering layer forming particulates 82, there may be used particulates of diamond, SiC, Al₂O₃, WC, TiN, TaC, ZrC, AlB, B₄C and the like. The particle diameter of the gettering layer forming particulates 82 is preferably not more than 1 μm, for example.

The material of the polishing pad 47 is not particularly limited; other than the non-woven fabric, there may be used polyurethane foam and porous fluoro-resin. The polishing pad 47 has numerous holes (pores), which penetrate the polishing pad 47 from the adhesion surface 47a to the polishing surface 47c to form numerous communication holes (communication pores). The polishing liquid is supplied from the. grooves 47b to the polishing surface 47c through the communication holes (see FIGS. 4A and 4B). In general, a polishing pad is formed in its center with a hole, and a polishing liquid is supplied through the hole to the polishing surface. In the present embodiment, since the polishing pad 47 has the communication holes, the polishing liquid supplied from the supply hole 46a can reach the polishing surface 47c through the communication holes, notwithstanding the polishing pad 47 is not formed in its center with a hole.

Besides, as the liquid binding material, there may be used, for example, a liquid obtained by dissolving polyurethane in a solvent. As the solvent, there may be used dimethylformamide, dimethyl sulfoxide, acetone, ethyl acetate and the like. The polishing pad 47 may contain two or more kinds of solid-phase reaction particulates 81. In addition, the polishing pad 47 may contain two or more kinds of gettering layer forming particulates 82.

As illustrated in FIG. 4A, the polishing tool 48 configured as above is detachably mounted to a lower face of the mounter 44 mounted to a lower end of the rotary spindle 43. The mounter 44 is formed with bolt insertion holes (not depicted) penetrating the mounter 44 from the upper face to the lower face thereof, and bolts 71 inserted in the bolt insertion holes are screw engaged with the female screw holes 46b (see FIGS. 3A and 3B) formed in the support base 46, whereby the polishing tool 48 is mounted to the mounter 44. In this instance, a passage 43a formed in the center of the rotary spindle 43 communicates with the supply hole 46a formed in the support base 46.

The passage 43a in the rotary spindle 43 is connected with an alkaline solution supply source 61 and a pure water supply source 62 through the valves 65 and 66, respectively. The alkaline solution supply source 61 and the pure water supply source 62 constitute the polishing liquid supply unit 60. An alkaline solution of the alkaline solution supply source 61 or pure water of the pure water supply source 62, as the polishing liquid, is supplied to the polishing pad 47 through the passage 43a and the supply hole 46a. In this instance, as depicted in FIG. 4B, the polishing liquid first passes through the grooves 47b formed in the adhesion surface 47a, to be distributed from the center side toward the outside of the polishing pad 47, and is then supplied from the grooves 47b to the polishing surface 47c through the communication holes.

Thus, in the polishing pad 47, the plurality of grooves 47b serving as passages for the polishing liquid is formed on the adhesion surface 47a side, and, therefore, it is unnecessary to form grooves on the polishing surface 47c side. This ensures that the polishing surface 47c can be formed to be flat, and, therefore, collision of the angular parts 94 (see FIG. 2) formed between the groove side surfaces 93 and the polishing surface 91 on the wafer W would not occur, and chipping of the outer peripheral edge of the wafer W can be avoided. Using the flat polishing surface 47c, the wafer W can be favorably polished by the solid-phase reaction particulates 81.

In addition, the polishing liquid is supplied from the polishing liquid supply unit 60 to the polishing pad 47 through the passage 43a and through the supply hole 46a of the support base 46, and is then distributed from the center toward the outside of the polishing pad 47 through the plurality of grooves 47b in the adhesion surface 47a. Further, the polishing liquid passes through the communication holes, thereby being supplied from the grooves 47b to the polishing surface 47c. In other words, the polishing liquid supplied through the supply hole 46a in the support base 46 spreads in the radial directions of the polishing pad 47 along the grooves 47b in the adhesion surface 47a, before reaching the polishing surface 47c. This ensures that the polishing liquid can be distributed throughout the polishing pad 47, edge chipping of the wafer W can be prevented, and the wafer W can be polished in a favorable manner.

The alkaline solution supply source 61 contains an alkaline solution. The alkaline solution in the alkaline solution supply source 61 preferably has a pH of 10 to 12. As the alkaline solution of a pH of 10 to 12, there may be used a solution of tetramethylammonium hydroxide (TMAH), piperazine, potassium hydroxide, sodium hydroxide, or the like. In addition, the pure water supply source 62 contains pure water. The pure water in the pure water supply source 62 may be supplied through a piping in the factory.

At the time of removing a grinding strain layer from the wafer W in a strain layer removing step which will be described later, the valve 65 is opened, and the alkaline solution is supplied from the alkaline solution supply source 61 into the passage 43a. The alkaline solution supplied into the passage 43a is distributed into the grooves 47b of the polishing pad 47, and further spreads over the polishing surface 47c through the communication holes. This permits the solid-phase reaction particulates 81 contained in the polishing pad 47 to function, whereby the wafer W can be polished.

At the time of forming a gettering layer on the wafer W in a gettering layer forming step, the valve 66 is opened, and pure water is supplied from the pure water supply source 62 into the passage 43a. The pure water supplied into the passage 43a is distributed into the grooves 47b, and further spreads over the polishing surface 47c through the communication holes, which permits the gettering layer forming particulates 82 contained in the polishing pad 47 to function, whereby the gettering layer can be formed on the wafer W.

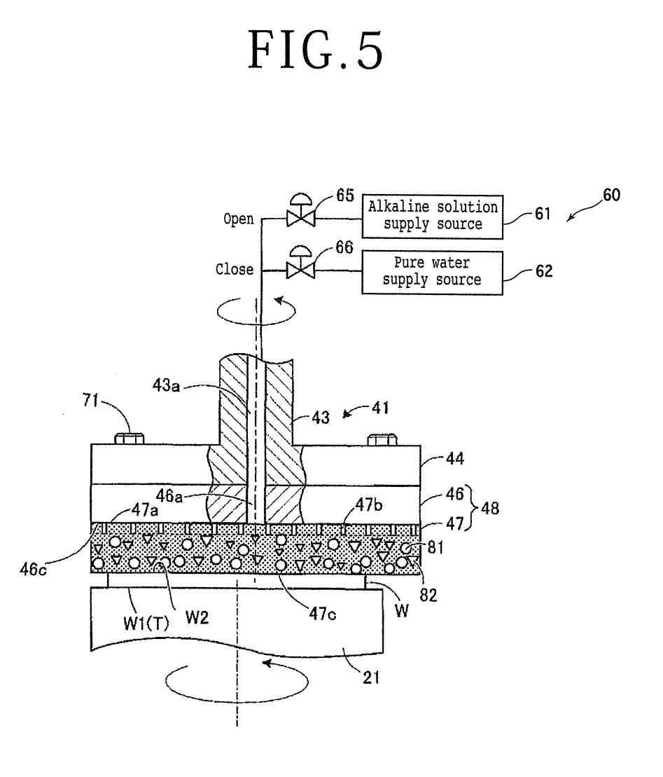

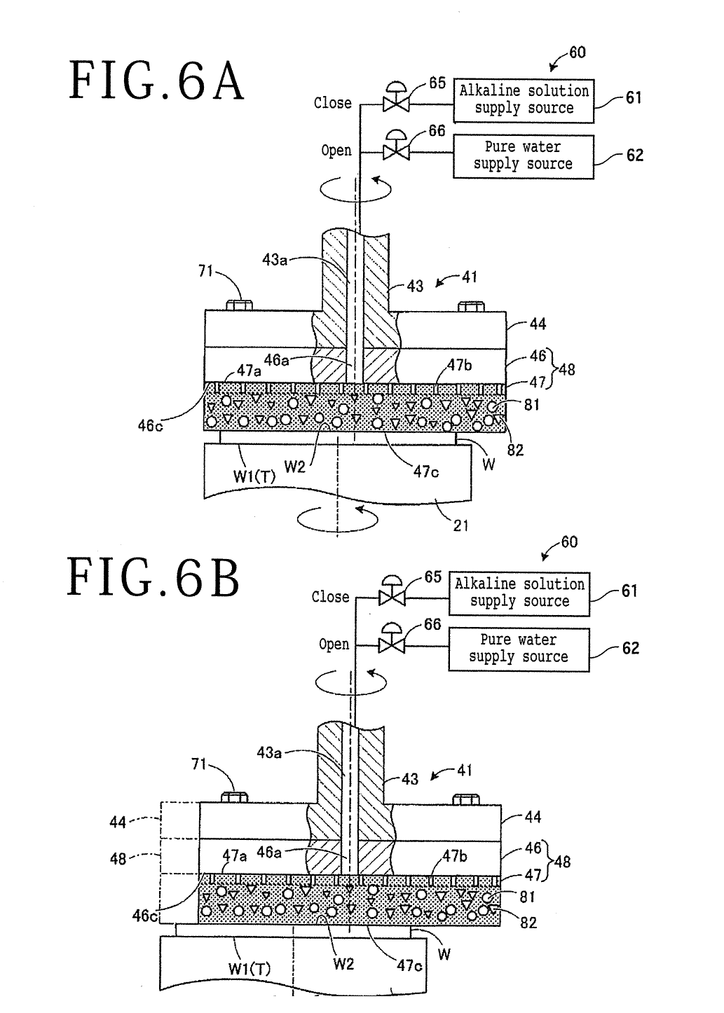

Referring to FIGS. 5, 6A and 6B, a method of processing the wafer W by the polishing pad 47 will be described. The method of processing the wafer W by the polishing pad 47 includes a strain layer removing step of polishing the back surface W2 of the wafer W by the polishing pad 47 while supplying the alkaline solution to remove the grinding strain layer, and a gettering layer forming step of forming flaws on the back surface W2 of the wafer W by the polishing pad 47 while supplying the pure water. FIG. 5 is a figure depicting the strain layer removing step according to the present embodiment, and FIGS. 6A and 6B are figures depicting the gettering layer forming step according to the present embodiment.

As illustrated in FIG. 5, the strain layer removing step is conducted first. The wafer W ground to a predetermined thickness is carried onto the chuck table 21, in a state in which the front surface W1 with the protective tape T adhered thereto is on the lower side and the back surface W2 is on the upper side, and the wafer W is held by the chuck table 21 through the protective tape T. In addition, the chuck table 21 is moved to a position beneath the polishing unit 41 by the moving means 24 (see FIG. 1), and is positioned such that the rotational axis of the chuck table 21 and the rotational axis of the polishing pad 47 are deviated from each other.

The chuck table 21 is rotated around the Z-axis, and the polishing pad 47 is also rotated around the Z-axis, in the same direction. Then, processing feeding of the polishing pad 47 toward the back surface W2 of the wafer W at a polishing pressure of, for example, 300 g/cm² is conducted by the processing feeding means 31 (see FIG. 1), and the polishing surface 47c of the polishing pad 47 is brought into rotating contact with the whole of the back surface W2 of the wafer W, whereby the wafer W is polished.

In this instance, the valve 66 is closed, whereas the valve 65 is opened, and the alkaline solution is supplied from the alkaline solution supply source 61 of the polishing liquid supply unit 60 into the passage 43a of the rotary spindle 43. By this, the alkaline solution is supplied to the polishing pad 47 at a rate of, for example, 0.5 L/minute, through the supply hole 46a formed in the support base 46. Under centrifugal forces due to the rotation of the polishing pad 47, the alkaline solution spreads toward the outside of the polishing pad 47 through the grooves 47b formed in the adhesion surface 47a of the polishing pad 47, and is supplied from the grooves 47b to the polishing surface 47c through the communication holes. The alkaline solution spreads over the polishing surface 47c, and the wafer W is polished. Note that the polishing rate is set to, for example, 0.72 μm/minute, and the polishing time is set to, for example, two minutes.

With the strain layer removing step thus conducted, the solid-phase reaction particulates 81 contained in the polishing pad 47 are permitted to function strongly, whereby the back surface W2 of the wafer W is polished by a predetermined amount, and is etched by the alkaline solution, resulting in that the grinding strain layer formed on the back surface W2 of the wafer W by grinding is removed.

As depicted in FIGS. 6A and 6B, after the strain layer removing step, the gettering layer forming step is performed. As depicted in FIG. 6A, the chuck table 21 is rotated around the Z-axis, and the polishing pad 47 is also rotated around the Z-axis in the same direction as the chuck table 21. Then, processing feeding of the polishing pad 47 toward the back surface W2 of the wafer W at a polishing pressure of, for example, 50 g/cm² is conducted by the processing feeding means 31 (see FIG. 1), and the polishing surface 47c of the polishing pad 47 is brought into rotating contact with the wafer W, whereby the wafer W is polished.

In this instance, the valve 65 is closed to stop the supply of the alkaline solution into the passage 43a, whereas the valve 66 is opened, to switch to the supply of pure water from the pure water supply source 62. By this, the pure water is supplied to the polishing pad 47 at a rate of, for example, 1.0 L/minute through the supply hole 46a formed in the support base 46. The pure water is distributed from the supply hole 46a into the grooves 47b in the adhesion surface 47a of the polishing pad 47, and spreads over the polishing surface 47c from the groove 47b through the communication holes.

As illustrated in FIG. 6B, in a state in which the polishing pad 47 is in rotating contact with the wafer W while the pure water is supplied to the polishing pad 47, the chuck table 21 is moved in the direction of arrow N by the moving means 24 (see FIG. 1). In other words, while the back surface W2 of the wafer W is sliding, the chuck table 21 is moved in such a manner that the rotational axis of the chuck table 21 and the rotational axis of the polishing pad 47 are spaced away from each other in the Y-axis direction. The movement of the chuck table 21 in the direction of arrow N is conducted, for example, at a moving velocity of 0.67 mm/second and for one minute, whereby the chuck table 21 is moved by approximately 40 mm. By this, slight flaws are formed on the back surface W2 of the wafer W.

With the gettering layer forming step thus conducted, the gettering layer forming particulates 82 contained in the polishing pad 47 are permitted to function strongly, whereby the gettering layer can be formed on the back surface W2 of the wafer W.

Since the plurality of grooves 47b serving as passages for the alkaline solution and the pure water are formed in the adhesion surface 47a of the polishing pad 47, the wafer W can be polished by the flat polishing surface 47c, so that there is no possibility that the angular parts 94 (see FIG. 2) between the groove side surfaces 93 and the polishing surface 91 might collide on the wafer W. This ensures that chipping of the outer peripheral edge of the wafer W can be prevented from occurring.

In addition, the alkaline solution and the pure water are supplied from the alkaline solution supply source 61 or the pure water supply source 62 to the polishing pad 47 through the passage 43a and through the supply hole 46a in the support base 46, and are distributed into the plurality of grooves 47b formed in the adhesion surface 47a. Then, by passing through the communication holes, the polishing liquid is supplied from the grooves 47b to the polishing surface 47c.

Thus, in the strain layer removing step, the alkaline solution can be distributed throughout the polishing pad 47, and, therefore, the solid-phase reaction particulates 81 can be made to function and the wafer W can be polished favorably. Besides, in the gettering layer forming step, the pure water can be distributed throughout the polishing pad 47, and, therefore, the gettering layer forming particulates 82 can be made to function and the gettering layer can be formed on the wafer W. As a result, the alkaline solution and the pure water can be distributed throughout the polishing pad 47, edge chipping of the wafer W can be prevented, and the gettering layer can be formed on the wafer W in a favorable manner.

As has been described above, in the polishing pad 47, the adhesion surface 47a to be adhered to the support surface 46c of the support base 46 is formed with the plurality of grooves 47b, and the polishing surface 47c is not formed with grooves, so that the wafer W can be polished by the flat polishing surface 47c. Since there is no possibility that the angular parts 94 (see FIG. 2) between the groove side surfaces 93 and the polishing surface 91 might collide on the wafer W, the wafer W can be polished with the abrasive grains (the solid-phase reaction particulates 81, the gettering layer forming particulates 82), while preventing chipping of the outer peripheral edge of the wafer W. In addition, the polishing liquid supplied through the supply hole 46a of the support base 46 is distributed to the plurality of grooves 47b formed in the adhesion surface 47a of the polishing pad 47, and, further, is supplied from the grooves 47b to the polishing surface 47c through the communication holes. As a result, the polishing liquid can be distributed throughout the polishing pad 47, and the wafer W can be favorably polished while preventing edge chipping of the wafer W from being generated, even where the wafer W is thin.

In the above embodiment, the adhesion surface 47a of the polishing pad 47 is formed with the grooves 47b in a grid pattern, but this configuration is not restrictive. The grooves 47b need only be formed in such a manner as to permit the polishing liquid supplied from the supply hole 46a of the support base 46 to spread in the radial directions; for example, the grooves 47b may be formed to intersect obliquely, or may be formed radially from the center toward the outer periphery of the polishing pad 47.

Besides, while the solid-phase reaction particulates 81 and the gettering layer forming particulates 82 are contained in the polishing pad 47 in the above embodiment, alkaline particulates may be contained together with the solid-phase reaction particulates 81 in the polishing pad 47. With pure water supplied to the polishing pad 47, the alkaline particulates are dissolved to produce an alkaline solution, and, therefore, it is unnecessary to provide the polishing apparatus 1 with the alkaline solution supply source 61 for supplying the alkaline solution, and the wafer W can be processed with a simple apparatus configuration.

In addition, in the above embodiment, the chuck table 21 is moved in the Y-axis direction by the moving means 24 (see FIGS. 1 and 6B) and the gettering layer is thereby formed on the back surface W2 of the wafer W in the gettering layer forming step, but this is not limitative. A configuration in which the polishing pad 47 is moved relative to the chuck table 21 may be adopted, provided that the polishing pad 47 can be moved in such a manner that the rotational axis of the chuck table 21 and the rotational axis of the polishing pad 47 are spaced away from each other while the back surface W2 of the wafer W is sliding.

Besides, while the semiconductor device wafer has been used as the wafer W in the above embodiment, various wafers such as semiconductor substrates, inorganic material substrates and packaged substrates may be used. As the semiconductor substrate, there may be used various substrates of silicon, gallium arsenide, gallium nitride, silicon carbide and the like. As the inorganic material substrate, there may be used various substrates of sapphire, ceramics, glasses and the like. The semiconductor substrates and the inorganic material substrates may be formed with devices, or may not be formed with devices. As the packaged substrate, there may be used various substrates for chip size package (CSP), wafer level chip size package (WLCSP), electro magnetic interference (EMI), system in package (SIP), or fan out wafer level package (FOWLP). In addition, as the wafer, there may be used lithium tantalate, lithium niobate, either after device formation or before device formation, and, further, green ceramics and piezoelectric elements.

Besides, while the protective tape T has been adhered to the front surface W1 of the wafer W in the above embodiment, a substrate may be adhered to the front surface W1 of the wafer W.

In addition, while the polishing apparatus for polishing a wafer has been taken as an example of the processing apparatus in describing the present embodiment, this configuration is not restrictive. The present invention is also applicable to other processing apparatuses by which a wafer W is processed while a processing liquid is supplied to a processing tool. For example, the present invention may be applied to a polishing apparatus and a cluster apparatus based on a combination thereof, and the like.

Besides, while the embodiments of the present invention have been described, entire or partial combinations of the embodiments may be used as other embodiments of the invention.

In addition, the embodiments of the present invention are not limited to the above embodiments, and various changes, replacements and/or modifications may be made without departing from the gist of the technical thought of the present invention. Further, if the technical thought of the present invention can be realized in other ways by the progress of technology or by other derivative technologies, the invention may be carried out by the other relevant method. Therefore, the scope of the claims cover all the embodiments that are included in the scope of the technical thought of the present invention.

While a configuration in which the present invention is applied to the polishing apparatus for polishing a wafer has been described in the present embodiment, the invention is also applicable to processing apparatuses for processing a wafer W while a processing liquid is supplied to a processing tool.

As has been described above, the present invention has effects of distributing a polishing liquid throughout a polishing pad, preventing edge chipping of the wafer even where the wafer is thin, and enabling favorable polishing of the wafer, and the invention is especially useful for a polishing apparatus for polishing a wafer.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A polishing apparatus polishing a wafer, comprising:
a chuck table that holds the wafer on an upper face thereof; and
a polishing unit that polishes the wafer held by the chuck table,
wherein the polishing unit includes a rotary spindle, a mounter fixed to a tip of the rotary spindle, and a polishing tool detachably mounted to the mounter,
the polishing tool includes a circular annular support base communicating with a polishing liquid supply unit and provided in its center with a supply hole through which to pass a polishing liquid, and a polishing pad adhered to a support surface of the support base,
the polishing pad contains abrasive grains, and is formed with a plurality of grooves in an adhesion surface to be adhered to the support surface, and
the polishing pad has a plurality of communication holes penetrating from the adhesion surface to a flat polishing surface which is a surface opposite to the adhesion surface, and the polishing liquid supplied from the supply hole is distributed into the plurality of grooves and is supplied to the polishing surface through the plurality of communication holes.

2. A polishing apparatus polishing a wafer, comprising:
a chuck table that holds the wafer on an upper face thereof; and
a polishing unit that polishes the wafer held by the chuck table,
wherein the polishing unit includes a rotary spindle, a mounter fixed to a tip of the rotary spindle, and a polishing tool detachably mounted to the mounter,
the polishing tool includes a circular annular support base communicating with a polishing liquid supply unit and provided in its center with a supply hole through which to pass a polishing liquid, and a polishing pad adhered to a support surface of the support base,
the polishing pad is formed by putting solid-phase reaction particulates inducing a solid-phase reaction with silicon into a liquid binding material, impregnating a non-woven fabric with the resulting material and drying the impregnated non-woven fabric, and is formed with a plurality of grooves in an adhesion surface to be adhered to the support surface, and
the non-woven fabric has a plurality of communication holes penetrating from the adhesion surface to a flat polishing surface which is a surface opposite to the adhesion surface, and the polishing liquid supplied from the supply hole is distributed into the plurality of grooves and is supplied to the polishing surface through the plurality of communication holes.
